(19) United States
(12) Patent Application Publication
(10) Pub. No.: US 2015/0353773 A1
(43) Pub. Date: Dec. 10, 2015

(54) METHOD FOR PRODUCING A METALLIC OR NON-METALLIC METAL-COATED SUBSTRATE, A METALLIC OR NON-METALLIC METAL-COATED SUBSTRATE, AND USE OF SAID SUBSTRATE

(71) Applicant: ROPAL EUROPE AG, Burgwald (DE)

(72) Inventors: Matthias Dornseif, Frankenberg (DE); Willi Braun, Allendorf/Eder (DE)

(21) Appl. No.: 14/759,909

(22) PCT Filed: Jan. 8, 2014
(86) PCT No.: PCT/EP2014/000015

§ 371 Date: Jul. 8, 2015

(30) Foreign Application Priority Data
Jan. 8, 2013 (EP) 13000063.1

(51) Int. Cl. C09D 183/04; C23C 22/83; C23C 14/22; C23C 22/76; C23C 14/35; C23C 14/58

(52) U.S. Cl. CPC C09D 183/04; C23C 14/35; C23C 14/58; C23C 14/22; C23C 14/221; C23C 22/76; C23C 22/83; C23C 2222/20

(57) ABSTRACT

Methods for producing a corrosion-protected and/or glossy, metallic or non-metallic metal coated substrate.

### TECHNICAL FIELD

The invention relates to a method for producing a, in particular corrosion-protected and/or glossy, metallic or non-metallic metal-coated substrate, as well as to a, in particular corrosion-protected and/or glossy metallic or non-metallic metal-coated substrate, and the use thereof.

### BACKGROUND

The visual refinement of any substrates, with which these substrates are given a metallic effect, has been known for a long time. Essential requirements for metallic substrates as well as for metal-coated substrates are excellent corrosion resistance and a pleasing visual appearance. Often the goal is to convey the impression of chromium-plated substrates. Substrates with a metallic gloss and corrosion resistant property profile are of particular significance in the automobile industry, e.g. when producing wheels or wheel rims, in particular, light metal wheels or wheel rims. A chromium gleaming appearance and resistance to typical use conditions are expected from such products.

For example, a method is known from prior art with which light metal wheel rims are galvanically chrome-plated. With this method, a chrome layer, which is only several thousandths of a millimeter thick, is applied to a light metal wheel rim. In order to avoid reproducing all the unevennesses of the substrate surfaces, the wheel rims must therefore be ground, high-gloss polished and thoroughly prepared before the galvanic coating process. Otherwise, all pores, scratches and unevennesses would clearly be seen on the coated wheel rim after the chrome-plating step. The process steps of grinding and high-gloss polishing require much time and work, even if the substrate geometry is not too challenging. Furthermore, the galvanic process is as such laborious in terms of work safety, and can harm the environment if it is not performed correctly. More often than not, contact corrosion will occur as soon as the galvanic chromium surface is damaged. Under the influence of e.g. rainwater or snow melt water, which generally contains dissolved road salt, an electric voltage series is created between the more precious part (in this case, chrome as the covering layer) and the less precious metal of the substrate (such as an aluminum or magnesium alloy or stainless steel). Here, the less precious metal disintegrates. As a result, e.g. a wheel rim can in an unfavorable case be severely damaged when inter-crystalline corrosion occurs, which can then lead to a critical effect on both the visual appearance and the stability levels of the wheel rim under dynamic load during use. It is furthermore of disadvantage with the galvanic chrome plating process that the galvanically applied chrome layer more frequently comprises a different expansion coefficient than the substrate material which lies beneath it. This alone can lead to tensions which result in fissures or even flaking Such damages typically cannot be eliminated by spot repair or masked.

DE 102 10 269 A1 discloses a method for adhesive coating of a substrate that is to give the substrate a metallic appearance. The substrate is first applied onto a base coat layer and dried. The base coat layer is then treated using an inorganic bonding agent. A silver layer is then applied. Finally, the applied layers are coated with a protective lacquer. With the substrates coated using this method, oxidation of the silver layer occurs relatively rapidly through the protective lacquer which is not completely sealed. This leads to a loss of adhesion of the silver layer from the substrate, and finally to a yellow discoloration.

In order to achieve sufficient corrosion protection of metal parts, coatings which contain chrome, also known as conversion layers, are frequently applied. Due to the light yellow iridescent effect of coatings of this type, the process is also referred to as yellow chromatizing. In contrast to anodically applied protective coatings, chromate conversion coatings no longer provide regular protection as soon as the surface is scratched. Chromatized surfaces can be obtained by means of the immersion method or the injection/spray method. Examples of the application of chromate protective layers can be found in U.S. Pat. No. 2,825,697 and U.S. Pat. No. 2,928,763. The application of a conventional conversion layer on a chrome base is also described, for example in WO 2004/014646 A1.

A modified chromate coating is given in WO 01/51681 A2, according to which a suitable passivation solution must contain chromium(III) chloride and sodium nitrate.

In DE 197 02 566 C2, the method for shine coating motor vehicle parts is finally modified with the aid of a chromate layer to the extent that a high-gloss layer made of a metal is applied in a vacuum to a powder lacquer layer present on the chromate layer using a magnetron. By means of this method, color effects can be systematically created without the necessity of adding external pigments.

It is furthermore known from WO 01/51681 A2 and DE 602 00 458 T2 that metal layers can be made resistant to corrosion not only by means of treatment with a chromate which contains a passivation or conversion solution, but that for this purpose, metal phosphate coatings which do not dissolve easily such as coatings with a zinc or iron phosphate base can also be used.

For the chrome-free surface treatment, according to DE 103 32 744 A1, an aqueous mixture containing an at least partially hydrolyzed, fluorine-free silane and an at least partially hydrolyzed silane which contains fluorine can also be used.

According to DE 602 00 458 T2, sufficient corrosion resistance can be achieved in that the corrosion protection coat contains a metallic zinc powder and at least one metal salt rust inhibitor, wherein this metal salt is based on magnesium, aluminum, calcium and barium, and has an average diameter size of no more than 1 μm. The metal in the metal salt must be more alkaline than zinc.

Good corrosion protection is achieved according to DE 100 49 005 A1 when the process step of treatment with a passivation agent occurs simultaneously with the application of a lubricant. The prerequisite for this is that the agent which contains lubricant does not essentially consist of titanium or/and zirconium and fluoride and a polymer. This new approach essentially makes use of long-chain molecule residues which, as is known from surface active substances such as tensides, tend towards self-assembly. Accordingly, this technology is also known as SAM coating (Self Assembling Molecules).

A chrome-free surface coating of metals, which can be applied at high coating speeds, is according to DE 101 49 148 A1 based on an aqueous composition which contains an organic film creating agent which contains at least one polymer which does not dissolve easily or which is dispersed in water, with an acid value in the region of between 5 and 200, at least one inorganic connection in particle form with an average particle diameter in the range of between 0.005 and 0.3 μm and at least one lubricant, wherein the dried film which is applied comprises a layer thickness in the region of between 0.01 to 10 μm, a pendulum strength of between 50 and 180 s and a flexibility which prevents fissures longer than 2 mm from occurring when bent over conical pin in accordance with DIN ISO 6860. Synthetic resins based on acrylates, butadienes, ethyls, polyester, polyurethane, silicon polyesters, epoxy resins, phenol, styrene and urine formaldehyde are suitable for use as organic film creation agents.

U.S. Pat. No. 6,896,920 B2 discloses a multi-layer gloss coating with which initially a polymer layer is to be applied to a metallic substrate surface. Then, this polymer coating is supplemented by a metal layer. An inorganic layer which prevents corrosion is then applied to this metal layer. The final, top layer of this multi-layer system is a transparent protective lacquer layer. Although it is identified as preventing corrosion, a corrosion-related change in the surface is determined after just 168 hours in the CASS salt spray mist test with the multi-layer substrates in accordance with U.S. Pat. No. 6,896,920 B2. The automobile industry regularly demands evidence of an unchanged surface even after 240 hours, however.

### BRIEF SUMMARY

It is the object of the present invention to provide a method for producing coated substrates, in particular, corrosion-protected and/or glossy coated substrates, as well as coated substrates, in particular, corrosion-protected and/or glossy coated substrates, which are free from the disadvantages of prior art. The object of the invention is in particular to provide a method with which, in particular, corrosion-protected substrates are accessible which are extremely corrosion-resistant even under mechanical load or following damage over a longer period of time, and which show or contain a very attractive visual appearance as is commonly obtained at best with galvanic chrome-plating. It is further the object of this invention to make accessible a method for producing, in particular, corrosion-protected and/or glossy coated substrates, which provides such coated substrates that are free from drips or smears, characterized by good adhesion of all layers, and in particular by improved adhesion of the outer protective or top coat, in a technically simple and reliable process. It was therefore also an object of the invention to make accessible a method for producing, in particular, corrosion-protected and/or glossy coated substrates, with which coated substrates with substantially improved adhesion of the outer protective or top coat are obtained. Finally, it was an object of the invention to provide substrates, in particular, corrosion-protected and/or glossy coated substrates that are characterized by low susceptibility to scratches.

This object is attained according to the invention by means of a method for producing a, in particular, corrosion-protected and/or glossy, metallic or non-metallic metal-coated substrate, comprising the following steps:

a) Providing at least one substrate with at least one, at least regionally, metal-coatable surface;

c) Applying at least one metallic composite protective layer, containing as a main component at least one first metal selected from the group consisting of aluminum, manganese, magnesium, chrome, and zinc, or at least one first metal alloy selected from the group consisting of steel, stainless steel, a magnesium alloy, a chrome alloy, and an aluminum alloy, and at least one second metal and/or at least one oxidically bonded second metal selected from the group consisting of zirconium, titanium, and hafnium distributed as a minor component in the main component, or composed of the main component and the minor component, wherein method step c) comprises the following sub-steps

i) Applying at least one metal layer, containing or composed of the at least one first metal or containing or composed of the at least one first metal alloy, onto the coatable surface of the substrate by means of vapor deposition and/or sputtering; and

ii) Treating the metal layer according to step i) with at least one, in particular acidic, first aqueous system, containing at least one first compound of the second metal;

such that preferably at least one first compound of the second metal and/or at least a second compound of the second metal that results from the at least one first compound during this treatment step, in particular when in contact with the metal layer and/or when migrating into the metal layer, and/or the second metal that results from the at least one first and/or second compound during this treatment step, in particular when in contact with the metal layer and/or when migrating into the metal layer is/are incorporated into the metal layer forming the composite protective layer and is/are present in the composite protective layer, in particular as a metal and/or in oxidically bonded form;

d) Silanizing the composite protective layer from step c) ii) by treating said composite protective layer with at least one, in particular alkaline, second aqueous system so as to form at least one polysiloxane layer, in particular directly on the composite protective layer; and

e) Applying at least one lacquer layer, in particular directly, onto the polysiloxane layer according to step d);

or comprising the following steps:

a′) Providing at least one substrate with at least one, at least regionally, metal-coatable surface;

c′) Applying at least one metal layer, containing or composed of the at least one first metal selected from the group consisting of aluminum, manganese, magnesium, chrome, and zinc, or containing or composed of the at least one first metal alloy selected from the group consisting of steel, stainless steel, a magnesium alloy, a chrome alloy, and an aluminum alloy, onto the coatable surface of the substrate by means of vapor deposition and/or sputtering;

d′) Silanizing the metal layer from step c′) by treating said metal layer with at least one, in particular alkaline, second aqueous system so as to form at least one polysiloxane layer, in particular directly on the metal layer; and

e′) Applying at least one lacquer layer, in particular directly, onto the polysiloxane layer according to step d′).

### BRIEF DESCRIPTION OF THE SEVERAL VIEWS OF THE DRAWINGS

FIG. 1a shows a schematic partial cross sectional view of a metallic substrate prior to performing the method according to the invention;

FIG. 1b shows the substrate from FIG. 1a following the application of a base coat layer;

FIG. 1c shows the substrate from FIG. 1b following the application of a metal layer;

FIG. 1d shows the substrate according to FIG. 1c, containing a metallic or composite protective layer;

FIG. 1e shows the substrate according to FIG. 1d, containing a polysiloxane layer; and

FIG. 1f shows the substrate according to FIG. 1e with a transparent top coat.

### DETAILED DESCRIPTION

At least one second metal and/or at least one oxidically bonded second metal is present in distributed or embedded form in the first metal or first metal alloy representing the first main component in the metallic composite protective layer. In one embodiment, the second metal and/or the oxidically bonded second metal are substantially evenly distributed in the first metal or the first metal alloy. In another embodiment, at least one second metal and/or at least one oxidically bonded second metal are distributed, in particular, evenly distributed across the entire thickness of the composite protective layer in the first metal or first metal alloy. The metallic composite protective layer can accordingly also be regarded as being an internal mixture containing a first metal or a first metal alloy wherein at least one second metal and/or at least one oxidically bonded second metal is present or embedded.

With the method according to the invention, a metal-coated substrate is obtained with a metallic composite protective layer, which as such is itself highly corrosion-protected, and in addition by means of the application of a substrate, said substrate also protects against corrosion insofar as it is a metallic substrate. While with non-metallic substrates the property of corrosion protection thus relates to the metallic protective layer, with metallic substrates, not only a metallic protection layer is obtained which is itself corrosion-protected, but instead this composite protective layer equips the metallic substrate with highly effective corrosion protection, all the more so when the metal of the metallic substrate and the first metal of the composite protective layer match. At the same time, this metallic composite protective layer is generally very glossy, so that high-gloss, highly resistant substrate surfaces are made possible. Corrosion-protected as defined by this invention means that the coated substrates provide a high level of corrosion protection and help prevent or reduce corrosion under typical conditions of use. Using the term corrosion-protected does not mean that a coated substrate is obtained that is absolutely corrosion resistant under all conceivable conditions. Instead, the objective is to allow for improved, more durable corrosion protection under regular conditions of use and optionally suitability for new applications.

Suitable substrates can be both of a metallic and of a non-metallic nature. For example, substrates containing or made of glass, carbon materials, ceramic or plastic can be considered as suitable non-metallic substrates. Particularly suitable plastics are PVC, polyolefins, in particular polypropylene, polyamide, polyester, polycarbonates, and polyoxyalkylenes, e.g. POM. In suitable substrates, non-metallic components or sections can be present alongside metallic components or sections. Suitable metallic substrates include, for example, magnesium, titanium or aluminum or metal alloys, in particular, magnesium, titanium or aluminum alloys, or stainless steel. In general, molds made of all metals, metal alloys and precious metals are suitable as metallic substrates. Substrates made of aluminum, iron, steel, stainless steel, copper, brass, magnesium, iridium, gold, silver, palladium, platinum, ruthenium, molybdenum, nickel, bronze, titanium, zinc, lead, tungsten, or manganese and their alloys are examples of suitable substrates. Preferred metal substrates or metal substrate surfaces comprise or in particular consist of aluminum or aluminum alloys, magnesium or magnesium alloys, or titanium or titanium alloys, or iron or iron alloys. Here, highly pure aluminum, magnesium or titanium is preferred, in particular with an aluminum, magnesium or titanium portion of at least 90% by weight, in particular at least 99% by weight in relation to the total weight of the metallic protective layer. For the metallic substrate, aluminum and aluminum alloys are particularly preferred for use.

The average thickness of the metallic protective or composite protective layer to be applied onto the substrate according to step c) of the method according to the invention, or the metal layer to be applied according to step c) i) is typically in the range between 5 nm and 500 nm, preferably in the range between 10 nm and 300 nm, and particularly preferred in the range between 20 nm and 200 nm. In particularly useful embodiments, this thickness in in the range from 50 nm to 150 nm. If too small thicknesses are selected, there is a risk of obtaining translucent layers. If layer thicknesses are too prominent, there may be adhesion problems depending on the application.

Very satisfactory results are for example obtained with layer thicknesses in the range between 50 nm and 120 nm. The results according to the invention can regularly already be obtained with layer thicknesses of less than 100 nm.

According to the invention, the first metal for the metallic protective or composite protective layer according to step c) or the metal layer according to step c) i), in particular includes aluminum, magnesium, or chrome, or the first metal alloy includes steel, stainless steel, or an aluminum, chrome, or magnesium alloy. A particularly suitable composite protective or metal layer comprises aluminum or an aluminum alloy.

In particular, it is preferred that the purity of the first metal, preferably of the aluminum, amounts to at least 80% by weight, preferably over 90% by weight, and best of all at least 99% by weight.

In a preferred embodiment, the first metal may be selected from the group consisting of aluminum, magnesium, and chrome, or the first metal alloy may be selected from the group consisting of steel, stainless steel, at least one magnesium alloy, at least one chrome alloy, and at least one aluminum alloy and/or the second metal may be selected from the group consisting of zirconium and titanium. In another preferred embodiment, the first compound of the second metal includes at least one oxide, double oxide, oxide hydrate, oxyhalogenide, halogenide, salt and/or an acid, in particular an acid. The second compound of the second metal preferably is an oxidically bonded second metal, in particular an oxide, double oxide, oxide hydrate, and/or oxyhalogenide.

Zirconium or zirconium compounds are preferred for use as the second metal. Any mixtures of compounds of the second metal may of course be used for producing the composite protective layer. Accordingly, any mixtures of second metals and/or of oxidically bonded second metals may be present in the same metallic composite protective layer. It can be seen that the method according to the invention is technically far removed from the standard galvanic chrome-plating process, and yet in terms of the glossy effect, gloss retention and corrosion resistance, at least equal results are achieved.

In the composite protective layer, the second metal or oxidically bonded second metal, preferably zirconium, is present in quantities between 0.2 and 10% by weight, preferably in the range from 1 to 7% by weight, and particularly preferred in the range from 1.5 to 5% by weight in relation to the overall weight of the metallic composite protective layer.

Oxidically bonded second metals also include double oxides such as aluminum and zirconium oxides.

Without being bound to any specific theory, it is presently assumed that the compounds of the second metal, which are present in the aqueous system e.g. as acids or salts, are present in the metallic composite protective layer after having been transferred into an oxidically bonded second metal or into said second metal.

Suitable acids of the second metals include, for example, hydrofluorozirconic acid (H₂ZrF₆), fluorotitanic acid (H₂TiF₆), and fluorohafnic acid (H₂HfF₆). Naturally, mixtures of different acids can also be used. These fluoric acids can be used both in their pure state and containing impurities such as fluoric acid. In the aqueous systems, the acids can be present e.g. in quantities of up to 5% by weight, in particular of up to 3.5% by weight in relation to the overall weight of the aqueous system. Fluoric acid can also be present in the aqueous systems e.g. in quantities in the range from 0.1 to 3% by weight.

Among the suitable salts, it is preferred that ammonium zirconium carbonate, which is for example available from Magnesium Electron Inc. under the brand name of Bacote 20, be used ((NH₄)₄[Zr(OH)₂(CO₃)₃].n H2O). Furthermore, alkali metal and ammonium fluorozirconates such as Na₂ZrF₆, KZrF₆, (NH₄)ZrF₆, as well as zirconium nitrates, zirconium oxynitrates, zirconium carbonates, zirconium fluorides or zirconium sulphate can also be used. These compounds of second metals can be used as such or in any mixture with each other.

In one embodiment, the oxides of the second metal can include zirconium oxides, titanium oxides and/or hafnium oxides, the oxyhalogenides of the second metal can include zirconium oxyhalogenides, in particular fluorides, titanium oxyhalogenides, in particular fluorides, and/or hafnium oxyhalogenides, in particular fluorides, the acids of the second metal can include fluorozirconic acid, fluorotitanic acid and/or fluorohafnic acid and/or the salts of the second metal can include fluorozirconates, fluorotitanates and/or fluorohafniates.

According to another embodiment of the method according to the invention, the deposition or sputtering technique in step c) or c′) includes physical vapor deposition (PVD), vapor deposition using an electron beam vaporizer, vapor deposition using a resistance vaporizer, induction vaporization, ARC vaporization and/or cathode spraying (sputter coating), in each case, in particular, in a high vacuum.

For the application of the metal layer according to step c) i) or step c′), the suitable deposition or sputtering methods include physical vapor deposition (PVD) coating, vapor deposition using an electron beam vaporizer, vapor deposition using a resistance vaporizer, induction vaporization, ARC vaporization and cathode spraying (sputter coating) can be used, in each case preferably in a high vacuum. These methods are known to persons skilled in the art. The metallic protective or composite layer or the metal layer can for example be applied onto the substrate or onto its coatable surface, onto the first base coat layer, the second base coat layer, and/or the bonding agent. Preferably, physical vapor deposition (PVD) coating is used. Here, resistance heated metal coil or metal shuttle vaporizers are used, wherein tungsten coils in a wide range of different forms are preferred. With the PVD method, in general, a vaporizer is equipped with coils which can be clamped onto vaporizer rails which are insulated from each other. A precisely determined quantity of a first metal or first metal alloy is preferably added to each coil. After the PVD system has been closed and evacuated, the vaporization can be started by switching on the power supply, as a result of which the vaporizer rails make the coils glow. The solid metal begins to melt and completely wets the coils, which are usually twisted. Following a further supply of power, the fluid metal is transferred to the gas phase, so that it can be deposited on the substrate to be coated.

The vaporization from metal shuttles proceeds in a similar manner. The vaporizer equipment is here in principle identical, but shuttles are usually used which are made of high melting metal sheets, such as tungsten, tantalum or molybdenum shuttles.

A further preferred method for depositing the metal layer on the substrate is cathode spraying (sputter method). Here, a cathode is arranged in an evacuated container which is connected to the negative pole of a power supply. The coating material which is sprayed is mounted immediately in front of the cathode, and the substrates to be coated are arranged opposite the coating material to be sprayed. Furthermore, argon can be fed through the container as a process gas which ultimately also comprises an anode which is connected to the positive pole of a power supply. After the container has been pre-evacuated, cathode and anode are connected with the power supply. Due to the systematic and controlled influx of argon, the central free path length of the charge carrier is significantly reduced. Argon atoms are ionized in the electric field between cathode and anode. The positively charged particles are accelerated with high energy to the negatively charged cathode. When they hit, and when the particles impact the coating material, said material is transferred to the vapor phase, is accelerated with high energy into the free space and then condenses on the substrates to be coated.

Further vapor deposition methods which can be used in the method according to the invention are performed using electron beam vaporization, resistance vaporization, induction vaporization and/or vaporization using a thermal, non-stationary arc (ARC vaporization).

Methods for applying a metal layer to a metallic or non-metallic substrate are incidentally also known to persons skilled in the art, and should also be included here, even if they are not named specifically.

According to a further development, the method according to the invention further comprises the following step between steps a) and c) or a′) and c′), respectively:

b) or b′) Applying at least one first base coat layer and optionally a second base coat layer to the, in particular metallic or plastic, substrate, and/or grinding and/or polishing the, in particular metallic, substrate surface.

For metallic substrates, a method has been shown to be particularly suitable comprising the following steps after step a):

b) Applying at least a first base coat layer onto the substrate and/or grinding and/or polishing the substrate surface.

c) i) Applying a metal layer comprising at least a first metal, a first precious metal and/or at least a first metal alloy onto the first base coat layer and/or onto the polished and/or ground substrate surface by means of physical vapor deposition (PVD) coating, vaporization by means of an electron stream vaporizer, vaporization by means of a resistance vaporizer, induction vaporization, ARC vaporization, cathode spraying (sputter coating), and/or by means of immersion or spraying, in particular in a vacuum, and

c) ii) Treatment of the metal layer with the first aqueous system containing at least an acid and/or a salt of a second metal, so as to form a metallic composite protective layer.

In this step, at least a second base coat layer can be applied to the first base coat layer.

Here, it is frequently advantageous that the first and/or second base coat layer are hardened after application in at least one subsequent heat treatment step and/or are annealed.

As an alternative to applying a first and, if appropriate, a second base coat layer or in addition to the application of a base coat layer, a pre-switched mechanical smoothing of the metal substrate surface can be provided, for example by means of grinding and/or polishing or vibratory grinding. Ground or polished metal surfaces frequently already have a surface quality of such a nature that when a metallic protective or composite layer is applied according to step c) of the method according to the invention, a highly corrosion-protected substrate is obtained.

The first and/or second base coat layer can for example be applied using a wet coating method and/or a powder coating method. Suitable examples are powder-type polyester resin compounds and epoxy/polyester powder. Suitable epoxy resins as base coat layer materials are known commercially under the brand name “Valophene”, for example. Base coat layers based on a urethane resin, as described in U.S. Pat. No. 4,431,711, are also suitable as first and second base coat layers. As an alternative, polyester or polyacrylic materials, as mentioned in WO 2004/014646 A1, can also be used. The wet coating method is most particularly preferred for the purpose of applying a base coat. Particularly preferred are those base coat application methods in which the curing of the base coat layer is achieved using UV radiation, rather than thermal curing. With the curing using UV radiation, no regular additional warming is required, even when in general no heat is generated during the process. Suitable powder coating, wet coating, and UV-curing layering systems and their application will be sufficiently familiar to a person skilled in the art. Depending on the quality of the surface (e.g. porous or raw), one or more base coat layers can be applied in order to smooth the surface. In particular with the first base coat layer, as can here be used on metal substrate surfaces in particular, an advantageous smoothing in of the surface is achieved in general. The base coat layer, in particular the first base coat layer, thus regularly represents a “smoothing layer”. With a base coat layer, all angle areas are in general reached, such that surface roughness can be smoothed even in these areas.

According to the invention, it can furthermore be provided that a standard conversion layer, e.g. such as the one described in U.S. Pat. No. 2,825,697 or U.S. Pat. No. 2,928,763, can be applied onto the substrate.

If the substrate is a metal substrate, it has regularly been shown to be advantageous to clean the surface of the substrate in a suitable manner, in particular when this metal substrate has been directly removed from the respective production process. For example, in a first, preparatory step, the metal substrate surface is degreased using alkaline or acid reagents. Degreasing agents of this type are offered for example by Henkel KGaA under the brand name Riduline®. In order to ensure that no degreasing reagents remain on the surface which may negatively affect the subsequent processing steps, a rinsing step with water is then regularly performed. Commercial degreasing steps are also known under the name of decoction or etching degreasing. As an alternative, a metal surface can be anodically degreased in an electrolyte degreasing bath.

Moreover, in some cases it has been shown to be advantageous to subject the surface of the metal substrate, in particular the degreased metal substrate surface to at least one pickling step. An acid rinsing bath is used, for example, for the pickling of the metal substrate surface. A suitable pickling solution therefore is diluted hydrochloric acid (1:10 v/v), for example. As a result, an essentially oxide-free metal surface is usually obtained.

In the same way as the degreasing step, the pickling step is generally completed by a rinsing step. Here, it has been shown to be very effective, at least towards the end of the rinsing procedure, and preferably during the rinsing procedure, to use deionized (DI) water.

In a preferred embodiment, the metallic protective or composite protective layer is applied to a degreased and/or pickled metal substrate surface in accordance with step c), or the metal layer in accordance with step c) i) or c′) of the method according to the invention. According to a further embodiment, the first and, if appropriate, the second base coat can also be applied to a degreased and/or pickled metal substrate surface.

If the metal substrate surface is polished and/or ground or vibratory ground, the degreasing and/or pickling step can frequently be omitted. Usually, with this type of surface treatment, sufficient material is removed from this surface, whereby impurities or other residues which are lying or adhering to the surface are removed as well. If the surface is polished or ground, it is moreover frequently possible to omit the application of a first and, if appropriate, a second base coat layer. With the polishing or grinding, an even or smooth surface is usually obtained of such a quality that no smoothing in by applying a base coat layer is then required. However, when the metal substrate comprises numerous angles and corners which cannot easily be adequately polished or ground, it can be advisable to subsequently conduct a first and, if appropriate, also a second base coat layer.

Glass and ceramic substrates are usually per se so smooth that no polishing step or application of additional base coat layers is required. This generally also applies to plastic substrates. If plastic substrates with a particularly smooth surface, in particular with a high degree of reliability, are required, at least one base coat layer is usually applied. Suitable base coat layers for plastic substrates are for example clear lacquers or UV lacquers. Wood substrates, and in some cases also ground and/or polished wood substrates, frequently require at least one base coat layer before the metallic protective layer or metallic layer can be applied, and therefore constitute plastic substrates in the meaning of this invention.

Plastic molded parts which can be treated with the method according to the invention can e.g. be made of ABS, SAN, ASA, PPE, ABS/PPE, ASA/PPE, SAN/PPE, PS, PVC, PC, ABS/PC, PP, PE, EPDM, polyacrylates, polyamides, POM or teflon. If a base coat layer needs to be applied to these plastic parts, these base coat materials are preferably applied using the wet coating method. With highly heat-resistant plastics, the powder coating method is also suitable.

According to a further optional embodiment of the invention, it is provided that before step c) at least one adhesive agent is applied to the surface of the substrate, the first base coat layer and/or the second base coat layer for the metallic protective layer or metallic layer, or is generated on said surface. A suitable adhesive agent can be generated or applied using e.g. at least one plasma pretreatment, preferably by means of at least one oxygen plasma and/or at least one polymer plasma, in particular comprising hexamethyl disiloxane. In addition, at least one inorganic or metal organic bonding agent can be applied as a bonding agent. Here, a tin(II) salt in an acidic solution or at least one amine-containing silane in an alkaline solution is preferably used.

Before the metallic protective or composite layer is applied according to step c), or the metal layer is applied according to step c) i), the substrate surface is preferably dried in order to be free of water residues.

Advantageously, the surfaces obtained after process step c) or process step c) i) are rinsed with water. It is preferred that at least towards the end of the rinsing step, and preferably during the rinsing step, deionized water is used.

The method according to the invention may include at least one heat treatment step after step c) or c) ii).

It is preferred that before the metal layer is treated according to step c) i) with the first aqueous system, the metal layer is wetted or rinsed with water, preferably DI water. It is preferred that the water used for this purpose has a conductance of less than 100 μS/cm, preferably less than 50 μS/cm, and particularly preferred less than 35 μS/cm.

The first aqueous system can for example take the form of a solution, a suspension or an emulsion. Preferably, the first aqueous system is used as a solution, i.e. the compounds, salts and/or acids named above are present in it in an essentially dissolved state, at least prior to application.

Naturally, it is also possible to add further ingredients to the first aqueous systems, alongside the aforementioned compounds or their mixtures. For this purpose, nitric acid, fluoric acid, phosphoric acid, salts of the named acids, ammonium bifluoride and ammonium sulfate are possible. Ammonium titanium fluoride constitutes a suitable titanium salt, for example.

Preferably, the first aqueous system contains fluoride ions in a free and/or complexed form. Fluoroborate salts and acids are suitable complexed fluoride ions, as are alkali metal and ammonium bifluorides. In very general terms, complex fluorides of titanium, zirconium, hafnium, silicon and/or boron are particularly suitable. It is preferred to use complex fluorides of zirconium.

Suitable first aqueous systems may further additionally contain at least one polymer compound which can be present in the aqueous composition in dissolved form, as an emulsion, or in the form of undissolved dispersed particles.

Among the polymer compounds, the polyacrylic acids and their salts and esters should be mentioned in particular. These acids, esters and salts can be present in the aqueous solution in a dissolved or dispersed form. The quantity of polymer components can be varied to a wide degree, and is preferably in the range between 0.1 and 0.5 g per liter.

Polymethyl vinyl maleic acid and polymethyl vinyl maleic acid anhydride are also potential polymer materials. Suitable polyacrylic acids ideally have a molecular weight of up to 500,000. Preferably, frequent use is also made of mixtures of possible polymer compounds. For example, mixtures containing polyacrylic acids, their salts or esters with polyvinyl alcohol should be mentioned in particular. Suitable polymers furthermore comprise hydroxyethyl ether of cellulose, ethylene maleic acid anhydride, polyvinyl pyrolidine and polyvinyl methyl ether.

Particularly preferred polymer components according to the basic principle of the present invention comprise a crosslinked polyester containing a large number of carbon acid functions and a large number of hydroxyl groups which may have reacted with each other either partially or fully. These crosslinked polyester polymers can for example be the reaction product of a first polymer containing carbon acid functions with a second polymer containing hydroxyl groups. For example, polyacrylic acids and polymethyl vinyl maleic acid anhydride can be used as first polymers of this type, while polyvinyl alcohol is a suitable second polymer. Interestingly, both the reaction product of the aforementioned first and second polymers and their mixture is a suitable component of the first aqueous system for the treatment according to the method of the invention. Moreover, an aqueous solution of this type can additionally preferably contain fluoric acids. Ammonium salts, for example, are potential suitable salts of the aforementioned polyacrylic acids.

In addition, as a suitable polymer, 3-(N—C₁₄-alkyl-N-2-hydroxethylaminomethyl)-4-hydroxystyrene is also a suitable polymer, in particular when it is used together with hexafluorozirconic acid. Furthermore, the homopolymer of the 4-hydroxystyrene can optionally also be present, with an average molecular weight in the range from 3000 to 6000. Related details are given in U.S. Pat. No. 5,089,064.

The first aqueous systems can also contain fatty acids, fatty alcohols and/or in particular fatty amines or any mixtures thereof. The fatty amines can also be present in the form of their ammonium salts. Fatty amines according to the basic principle of the present invention thus also include the corresponding ammonium salts. Here, compounds with saturated fatty alkyl chains are preferably used. The length of the linear fatty alkyl chains is preferably in a range from C₈ to C₂₄. Preferred fatty amines or the corresponding ammonium compounds are based on a C₁₂, C₁₄, C₁₆ or C₁₈ alkyl residue. Suitable fatty acids include e.g. capric acid.

Furthermore, polyoxyalkylene glycol ether, in particular polyoxyethylene glycol ethers, polypropylene glycol ethers and mixtures thereof can be added to suitable aqueous systems. All standard commercially available glycol ethers can be used for this purpose.

Suitable pH values for the first aqueous systems are or are kept preferably in the range between 1.5 and 6.5, preferably in the range between 1.5 and 5.0, and in particular between 2.0 and 4.5. If the pH of the aqueous systems is to be increased, additions of ammonia or ammonium hydroxide are above all suitable for this purpose, e.g. in the form of a 3% ammonia solution. In addition, conventional bases known to persons skilled in the art can be used.

Suitable pH values for the first aqueous systems are preferably in the range between 100 and 2000, preferably in the range between 150 and 1500, and in particular between 200 and 1000 μS/cm.

The optional components of the first aqueous system described above can in one embodiment also be present in the metal layer, either individually or in any combination, and are then also a part of the metallic composite protective layer.

According to an advantageous embodiment of the present invention, it is provided that after the metal layer has been applied according to step c) i), and prior to the treatment step c) ii) and/or after step c), the substrate thus coated is subjected, in particular directly, to a rinsing step with water, in particular fully desalinated water. Following this process, preferably at least one drying step is performed to dry the respective surface. The drying step can be performed e.g. at temperatures in the range between 120 and 180° C., for example at approximately 140° C. It is preferred that the water used for rinsing has a conductance of less than 60 μS/cm, preferably less than 50 μS/cm, and particularly preferred less than 35 μS/cm. In particular, the last rinsing cycle prior to the next process step or prior to a drying process has the conductance values mentioned above.

The pH value and/or conductance of the first aqueous system are preferably kept substantially constant, in particular within the ranges mentioned above, for the time the metal layer is treated.

The substrate which is coated with the metal layer can be treated e.g. by immersion, rinsing or spraying with the aforementioned first aqueous system, containing at least one of the named compounds of the second metal. The metal layer is preferably treated with this first aqueous system under increased pressure, for example in the form of high-pressure water jets. It has proven advantageous to direct a plurality of fine individual water jets at the substrate. The variant of spraying with the first aqueous system has accordingly proven to be particularly useful. Suitable pressures for the treatment with the first aqueous system are e.g. above 0.2 bar, preferably in the range between 0.5 and 50 bar, and particularly preferred in the range between 0.2 and 15 bar, in particular between 0.9 and 1.5 bar. These pressures are measured on the surface of the metal layer. With the variant described above, at least one acid, oxide, double oxide, oxide hydrate, halogenide, oxyhalogenide and/or salt of a second metal, preferably zirconium or titanium, can be incorporated into the metal layer.

Suitably, the temperature of the first aqueous system during the treatment of the substrate lies in the range between 15 and 50° C., preferably in the range between 20 and 40° C. Usually, a treatment period of between 20 and 120 seconds is sufficient in order to obtain the substrate according to the invention.

Preferably, the substrate equipped with a metal layer, in particular with an aluminum layer according to stage c) i) is treated directly after the application of said layer to the substrate surface with the first aqueous system described, as mentioned above. This procedure is performed in a production chain, for example, in which the substrate is subjected to all production steps in succession.

In a preferred embodiment, the share of iron ions in the first aqueous system does not exceed 10 ppm.

For the silanization of the composite protective layer, the step d) can include the treatment of the composite protective layer from step c) or the metal layer from step c′) with a second aqueous system containing at least one silane compound capable of polycondensation and/or polyaddition reactions, in particular hydrolyzable and/or at least partially hydrolyzed silanes.

In a suitable embodiment, the second aqueous system is alkaline and preferably has a pH of 8 to 12, preferably of 9 to 11.

In a particularly useful embodiment, the silanization in step d) or d′) is performed in such a manner that average layer thicknesses in the range from 5 nm to 2 μm, in particular to 1 μm, are obtained. Greater average layer thicknesses, such as 30 μm and more are possible, of course. Typically selected average layer thicknesses are in the range from 0.1 μm to 2 μm or 0.2 μm to 0.8 μm.

The silanization step can typically be divided into an application step in which the composite protective layer is treated with the second aqueous system and a drying step in which the water or solvent is removed, and a curing step. Drying and curing step can be combined into a single step in an embodiment. The curing step includes regular polyaddition or condensation reactions. Temperatures in the range from 120 to 350° C. can be used for the curing step, e.g. for a duration of 15 to 60 minutes.

Furthermore, silanization according to step d) or d′) can include the linking of silane compounds to the metal surface deposited or sputtered on, and polycondensation of linked silane compounds among each other and optionally of linked silane compounds and silane compounds not linked to the metal surface.

Suitable silane compounds for the silanization include functionalized hydrolyzable and/or partially and/or fully hydrolyzed alkoxysilanes, preferably containing amino, acryl, vinyl and/or epoxy groups, particularly preferred aminoalkyl trialkoxysilanes, e.g. aminoalkyl triethoxysilanes or 3-aminopropyl triethoxysilane.

Other examples of suitable silane compounds include 3-glycidoxypropyl tri(m)ethoxysilane, 3,4-epoxybutyl tri(m)ethoxysilane, 2-(3,4-epoxycyclohexyl)ethyl tri(m)ethoxysilane, 3-(meth)acryloxypropyl tri(m)ethoxysilane, 2-(meth)acryloxyethyl tri(m)ethoxysilane, 3-glycidoxypropyldimethyl(m)ethoxysilane, 3-glycidoxypropylmethyl di(m)ethoxysilane, 3-(meth)acryloxypropylmethyl di(m)ethoxysilane, 2-(meth)acryloxyethylmethyl di(m)ethoxysilane and any mixtures of these compounds.

Suitable polysiloxanes may also include partially fluorinated or perfluorinated siloxanes.

In addition to these silane compounds equipped with a functional group, which can attach to the surface of the composite protective layer, silane compounds without such functional linking units can be used in silanization, such as hexadecyl tri(m)ethoxysilane, cyclohexyl tri(m)ethoxysilane, cyclopentyl tri(m)ethoxysilane, ethyl tri(m)ethoxysilane, phenylethyl tri(m)ethoxysilane, phenyl tri(m)ethoxysilane, n-propyl tri(m)ethoxysilane, cyclohexyl(m)ethyl dimethoxysilane, dimethyl di(m)ethoxysilane, diisopropyl di(m)ethoxysilane, phenylmethyl di(m)ethoxysilane or any mixtures thereof.

In a particularly preferred embodiment, silanization according to step d) or d′) is not performed as a no-rinse process. This means that silanization according to step d) or d′) is preferably interrupted by rinsing with water, preferably desalinated water, e.g. DI water. A dripping step can be inserted before the rinsing step.

It has further proven useful in an embodiment of the method according to the invention that silane compounds are used for silanization which have functional groups that do not completely react and enter into at least one covalent bond with the top coat or lacquer layer during the production of said coat. Accordingly, it has proven useful in one embodiment to use such materials for the top or lacquer layer that contain at least one silane compound, preferably at least one silane compound capable of polycondensation and/or polyaddition reactions, especially via hydrolyzable and/or at least partially hydrolyzed silanes. In one embodiment, the silane compounds specified above for the second aqueous system can be used, either individually or in any mixture.

It is also advantageous in one embodiment of the method according to the invention to subject the coatable surface of the substrate before applying the at least one metal layer or the first and/or second base coat layers to at least one degreasing step, in particular including treatment with an acidic and/or alkaline degreasing agent and or treatment with an anodic degreasing bath, optionally followed by a rinsing step with water, in particular desalinated water, and/or at least one pickling step, optionally followed by a rinsing step with water, in particular desalinated water.

Interrupting the silanization step by rinsing with water regularly improves the adhesion of the following top coat or protective lacquer layer. In addition, this also is a better way to coat geometrically challenging components reliably and repeatably and to obtain a highly corrosion resistant and/or glossy coated component.

In a preferred embodiment of the method according to the invention, the preferably degreased substrate that has preferably been coated with a metal layer deposited or sputtered onto a first and optionally a second base coat layer, is sprayed with the first aqueous system, preferably for a duration from 3 to 120 seconds, particularly preferred for a duration from 10 to 60 seconds. After the treatment with the first aqueous system, the substrate in this preferred embodiment is rinsed with water, in particular desalinated water, for example DI water, in particular by spraying. The following step in this embodiment, preferably after allowing the rinsing water to drip off, is the treatment with the second aqueous system, preferably also by spraying. Treatment time with the second aqueous system is preferably set to a time between 5 and 180 seconds, particularly preferred to a time between 25 to 120 seconds, and even more preferred to a time between 40 and 90 seconds. The treatment time with the second aqueous system is regularly set as a function of the intended thickness of the siloxane layer. Treatment with the second aqueous system is followed, optionally after inserting a dripping step, by a rinsing step with water, preferably desalinated water, e.g. DI water. The method according to the invention, in particular if performed in accordance with the preferred embodiment specified above, results in very high process precision and yields a very even thickness of the siloxane layer. In addition, particularly good adhesion of the following top coat or protective lacquer layer is obtained. This also applies to geometrically challenging components.

With the invention, it is also suggested that after step c) or c) ii), at least one protective lacquer layer or top coat is applied, in particular a transparent one. This can for example be a protective coat or a clear coat or a transparent powder, which is preferably applied using a wet coating or powder coating method. Furthermore, the invention provides that the protective lacquer or top coat can contain at least one dye or one pigment.

Glazes known to a person skilled in the art may also be used as lacquer or top coat. These can be used to create in a simple manner e.g. bronze, titanium and gold tones, as well as individual color tones such as red, blue, yellow, green etc. and all eloxy colors.

The object of the invention is further achieved by a metal-coated substrate, in particular a corrosion-protected and/or glossy metal-coated substrate, comprising, in this order, a substrate;

at least one metallic composite protective layer, containing as a main component at least one first metal selected from the group consisting of aluminum, manganese, magnesium, chrome, and zinc, or at least one first metal alloy selected from the group consisting of steel, stainless steel, a magnesium alloy, a chrome alloy, and an aluminum alloy, and at least one second metal and/or at least one oxidically bonded second metal selected from the group consisting of zirconium, titanium, and hafnium distributed as a minor component in this main component, or composed of the at least one main and the at least one minor component, wherein the first metal or the first metal alloy has been applied as a metal layer by means of vapor deposition or sputtering;

at least one polysiloxane layer, in particular present directly on the composite protective layer or at least partially covalently bonded to the composite protective layer;

at least one lacquer layer, in particular present directly on the polysiloxane layer or at least partially covalently bonded to the polysiloxane layer;

a substrate;

at least one metal layer, containing at least one first metal selected from the group consisting of aluminum, manganese, magnesium, chrome, and zinc, or at least one first metal alloy selected from the group consisting of steel, stainless steel, a magnesium alloy, a chrome alloy, and an aluminum alloy, wherein the first metal or the first metal alloy has been applied as a metal layer by means of vapor deposition and/or sputtering;

at least one polysiloxane layer, in particular present directly on the metal layer or at least partially covalently bonded to said metal layer; and at least one lacquer layer, in particular present directly on the polysiloxane layer or at least partially covalently attached to said polysiloxane layer.

The coated substrates according to the invention, i.e. the metal-coated substrates, preferably are substrates obtained in accordance with the method of the invention.

The substrates according to the invention can for example be used as mirrors, mirrored material or as accessory parts for the automobile construction sector. They can also be used as light metal wheel rims or light metal wheels for the automobile construction sector. Naturally, car body components, whether they are made of plastic or metal, can be provided with a metallic protective or composite protective layer according to the invention. The substrates according to the invention are naturally not restricted to the uses named above.

Accordingly, the present invention comprises metal-coated metallic and non-metallic substrates, comprising, in this order, one substrate, for example made of plastic, aluminum or an aluminum alloy, and a metallic protective or composite protective layer as described above, in particular based on aluminum. In this embodiment, the substrate surface to be equipped with the metallic protective or composite protective layer can optionally be present in a ground and/or polished form. In another, preferred embodiment, the coated structure according to the invention comprises in this order one substrate, preferably with a ground and/or polished substrate surface, one, optionally chrome-free, conversion layer and a metallic protective or composite protective layer as described above. According to a further advantageous embodiment, a coated substrate according to the invention comprises in this order one substrate, optionally with a polished and/or ground surface, a first and optionally a second base coat layer and a metallic protective or composite protective layer, as described above. Furthermore, an alternative coated substrate according to the invention comprises in this order one substrate, optionally with a polished and/or ground substrate surface, one, optionally chrome-free, conversion layer a first and optionally a second base coat layer and a metallic protective or composite protective layer, as described above.

The method according to the invention and the substrates according to the invention are in one embodiment chrome-free, i.e. the composite protective layer or the metal layer do not contain chrome, neither as a metal nor in the form of a chrome compound, such as an oxide or salt. In addition, in one variant the substrates can also be free of chrome or chrome compounds.

The semiquantitative representation of the lateral distribution of the elements of the composite protective layer, e.g. Zr, Al, and O, can be obtained by analyzing an EDX element map (EDX=energy dispersive x-ray microanalysis). This result was obtained on the basis of energy dispersive x-ray microanalysis coupled with ESEM technology (Environmental Scanning Electron Microscopy; grid electron microscopy) (e.g. with an excitation voltage of 10 keV). The image was obtained with secondary electrons (SE topography contrast) or with reverse sprayed electrons (BSE material contrast). For the EDX image as well as for the measuring methods described below, it is recommended to produce a microtome cross cut of the specimen at a wide angle (e.g. modification factor of approx. 400). In order to have an adequate measuring area or length available, it was necessary to cut the analyzed specimen diagonally. This made it possible to lengthen the measuring length to approximately 400 μm over the metallic composite protective layer 11 with a thickness of only approximately 100 nm. With this cutting method, it can never be completely prevented with any regularity that material from other layers is incorporated into adjacent layers or smeared.

The result of the EDX measurement can be confirmed by a line scan analysis over the surface of a microtome main body section, which can also be used as an alternative. TOF-SIMS measurements are taken at discrete consecutive measuring points. The image is normalized based on the sum total of the intensities of selected hydrocarbon signals. The intensity of characteristic signals was analyzed, for example, using mass spectroscopy at 20 measuring points along a line scan length of approximately 600 μm. The line scan can extend over the entire width of the metallic composite protective layer and also cover the top coat and base coat layer sections which are attached to the protective layer. TOF-SIMS is a flying time secondary ion mass spectrometry method for the highly sensitive indication of elements and inorganic and organic compounds on material surfaces. This method allows analyses in the μm and nm range regardless of location.

XPS spectra can be used to determine the bonding states of components of the composite protective layer. X-ray excited photoelectron spectroscopy (XPS) enables the determination of bonding states alongside the quantitative identification of the elements present in the immediate surface proximity in solid bodies. An XPS deep profile analysis of the composite protective layer provides information about the distribution of the second metals in the metal layer made of the first metal.

The invention is based on the surprising finding that as a result of the method according to the invention, a substrate with a metallic protective layer is provided which comprises excellent corrosion resistance as well as a highly attractive chrome appearance. A chrome appearance is one which is generally only achieved with the galvanic chrome-plating of substrates. A visual appearance of this nature is not achievable with the methods known in prior art. With the method according to the present invention, a corrosion resistant, very shiny substrate with a strongly adhesive coat can be obtained even with complex geometry, which in terms of visual appearance is identical to galvanically chrome-plated substrates, while additionally meeting all test standards specified by the automobile industry. In particular, excellent adhesion of the protective or top coat is achieved.

The substrates according to the invention show surprising levels of corrosion resistance, even when the surfaces have been subjected to mechanical damage, such as from stone impact or scoring. It was in particular not to be anticipated that metal substrates, in particular aluminum substrates, could be obtained that have the gloss that is otherwise only seen in particularly high quality chrome components. The advantageous effects in terms of corrosion resistance and gloss naturally also occur when no base coat layer is applied to the substrate.

In contrast to standard methods, the method according to the invention stands out due to the use of environmentally compatible composite elements. The method according to the invention can be used for the manufacture of a wide range of glossy components. Wheel rims are one example, such as automobile, motorbike and bicycle wheel rims, as well as decorative objects of all types, e.g. decorative strips, car body exterior and interior components such as rear mirror coverings, front covering panels, engine hood covers and consoles, sanitary facility objects such as taps, and reflector surfaces such as with headlights, in particular car headlights. Furthermore, all types of handles, such as door handles, and all types of frame, such as window frames, as well as packaging objects and cases such as for the cosmetics sector, e.g. lipstick cases, can be produced using the method according to the invention. In addition, a wide range of engine and bicycle components for example, or other means of transport, and assembly components as used in the furniture sector, as well as pipes, hand towel rails, radiators, elevator components, interior and exterior components for airplanes, all types of reflector, jewelry, mobile phone cases or components used in building construction can be coated using the method according to the invention. The substrates which are coated according to the invention are also particularly suitable for use in shipbuilding and can be used both for interior and, in particular, exterior components. The quality of the products coated according to the invention is reflected in the fact that long-term corrosion resistance and therefore also a high-quality chrome-like gloss is not diminished even by seawater, e.g. sea spray.

Furthermore, it is of particular advantage that problems caused by different expansion coefficients, such as those which are regularly observed with galvanically chrome-plated substrates, no longer occur. The substrates which are coated using the method according to the invention no longer tend to form fissures, nor to flake. In this manner, for example, very shiny plastic substrates become possible, which can be used for a wide range of applications, for example in automobile construction or home appliances.

The substrates which are coated using the method according to the invention consistently meet the required specified values for the chemical resistance test according to VDA (the German Association of the Automotive Industry) test sheet 621412 (test A). Furthermore, the substrates according to the invention typically show no change to the surface even after 240 hours in a salt spray mist test according to DIN 50021-CASS (copper chloride/acetic acid). By contrast, with the multiple layer system disclosed in U.S. Pat. No. 6,896,970 B2, wherein a conversion layer is provided on a layer structure consisting of a polymer layer and a metal layer, with the CASS test, a change in the surface was determined after just 168 hours. With the substrates according to the invention, neither the formation of blisters nor base metal corrosion was observed. In addition, the substrates coated according to the invention achieve in the stone impact test according to PV 1213 regular characteristic values ranging from 0 to 0.5. Furthermore, the condensation water constant climate test according to DIN 50017 shows no change to the surface after 240 hours. Finally, these coated substrates also show no change in the outdoor exposure test (Florida test) over a longer period of outdoor exposure lasting several months. Retention of gloss according to DIN 67530 is consistently almost 100%. The cross-cut characteristic determined in a cross-cut test according to DIN EN ISO 2409 consistently is GT 0.

The coated substrates obtained using the method according to the invention meets both the standards set by the automobile industry for resistance of the coating, and the legal standards relating to the permission to use the coating system for the treatment of car wheel rims. Furthermore, the method according to the invention provides a coat of high quality visual appearance in such a manner that a chrome appearance and a very highly resistant surface are achieved with a comparatively low level of effort.

In particular, the method according to the invention has the advantages that it is not necessary to high gloss polish the substrates to be coated, e.g. light metal wheel rims, which with a complex geometry is only possible, if at all, with a very high level of effort. The preparation of the substrate is thus significantly less complex. It should furthermore be emphasized that the method according to the invention is environmentally compatible, since solvent emissions are substantially completely avoided. The method according to the invention provides a coated substrate with constant corrosion protection even when the layer system is harmed or damaged right through to the substrate. This significantly increases the working life of a substrate coated according to the invention. In particular when the substrates according to the invention are used in the automobile industry, such as for light metal wheel rims or reflectors for headlights, this resistance capacity has a positive effect. Furthermore, substrates of this type have an excellent visual appearance and can thus also be used in product design, such as when using the substrate as a wheel or wheel rim. Overall, the general visual impression of the car is improved, and with it its visual appeal over standard designs.

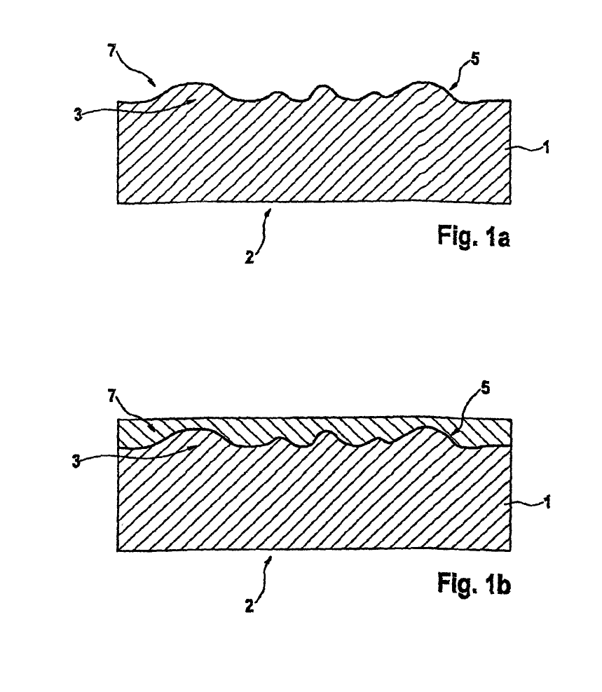

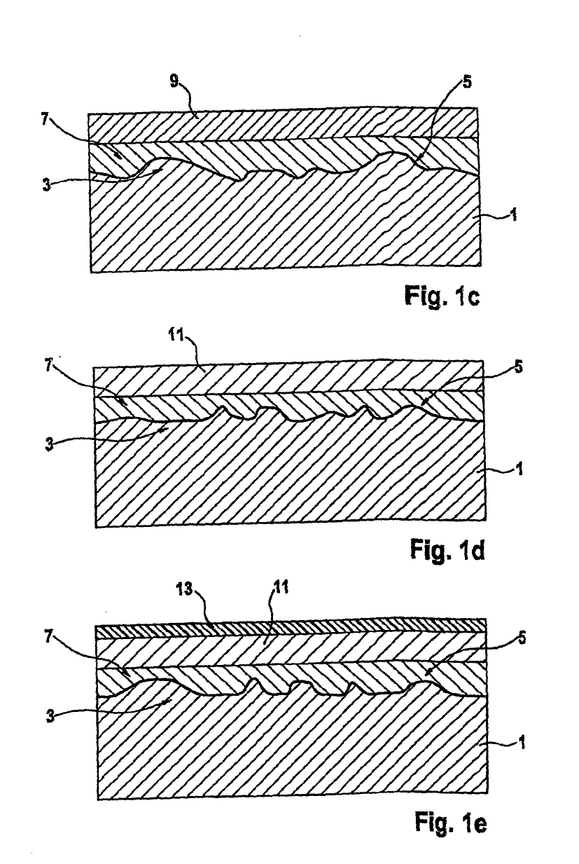

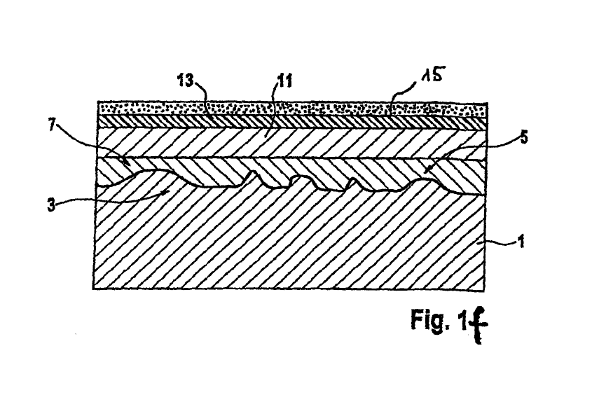

Further features and advantages of the invention are included in detail in the following description, and in the exemplary embodiments of the invention with reference to schematic drawings. The sequence of an embodiment of the method according to the invention will now be explained with reference to the coating of a light metal component. FIG. 1a shows a schematic partial cross sectional view of a metallic substrate 1 in the form of a cross-section of an aluminum light metal component 2. The unevennesses 3 of the metal surface are exaggerated and shown schematically for better illustration. First, the surface of the substrate 1 can be degreased in two etching steps. This serves the purpose of removing separating agent residues from the substrate production process which may be present on the surface of the substrate 1. In particular, these two degreasing steps are performed in such a manner that the light metal component 2 is first immersed in a preferably alkaline etching bath. In a second etching step, the light metal component 2 is bathed in a 60° C., preferably alkaline, etching bath. The light metal component 2 is then freed from etching residues by rinsing. Then, the surface of the light metal component 2 or of the substrate 1 can be subjected to a pickling step with e.g. an acidic agent in order to remove an existing oxidation layer. After rinsing with water and then preferably with fully desalinated water, a first base coat layer 5 can be applied to the substrate 1 (see also FIG. 1b). Preferably, the application of the base coat layer is performed using a wet coating method. After the base coat is applied, a heat treatment or tempering stage preferably follows, in order to achieve a curing or burning in of the base coat layer 5. As can particularly be seen in FIG. 1b, a significantly more even surface 7 is obtained by the base coat layer 5 compared to the surface 3 of the substrate.

As an option, a further, second base coat layer which is not shown in this exemplary embodiment can be applied to the base coat layer 5 for the purpose of further evening out the surface. This is used in particular to generate an optimally smooth surface, an optimum surface hardness and again, to achieve an optimized surface tension. A light metal component 2 which is prepared in this manner can be subjected to the steps of the method according to the invention. Naturally, every non-pretreated metallic substrate can also be subjected to the method according to the invention, in particular in a polished and/or ground state.

For this purpose, as can be seen in FIG. 1c, a metal layer 9 made of e.g. aluminum is applied to the substrate 1 or the base coat layer 5, preferably in a cathode spraying process. The average thickness of the metal layer can approximately be between 50 and 120 nm.

In a subsequent step, a heat treatment or tempering of the aluminum layer 9 can optionally be performed, which is preferably done at a temperature of approximately 140° C.

As an option, a bonding agent can be created between the base coat layer 5 and the aluminum layer 9, in particular because of the fact that a plasma pretreatment takes place in the vacuum chamber which is used for cathode spraying. As a result of this plasma pretreatment (smoldering) in an inert gas atmosphere (preferably comprising argon), a “base coat” can be applied. Such creation of a bonding agent of this type (not shown) on the surface of the first base coat 5 also offers economic advantages, since in the later cathode spraying process, the pressure in the vacuum chamber does not generally need to be kept as low, as a result of which the pump-down time of the vacuum chamber can be reduced by approximately 75%, which in turn increases the flow rates. For this purpose, preferably a polymer such as hexamethyl disiloxane is added to the plasma chamber while the plasma is being created.

In the present embodiment, the application of the aluminum layer 9 is followed, in particular directly afterwards, by treatment with a first aqueous system containing zirconic acid (H₂ZrF₆) and/or zirconium salts such as zirconium carbonate, for example ammonium zirconium carbonate, and/or zirconium oxynitrate and optionally zirconium dioxide and/or fluoric acid. The first aqueous system has a pH of about 2.5 and a conductance of less than 100 μS/cm here. The pH can be set using diluted ammonia solution.

For the production of the aqueous system, fully desalinated water is preferably used. Advantageously, the substrate which is coated with the aluminum layer is treated with the aqueous system described using suitable nozzles with a plurality of high-pressure jets, preferably at a pressure greater than 0.5 bar. As a result of, or during, this treatment process, the compounds of the zirconium described above are incorporated into the aluminum layer, substantially across its entire thickness. This layer includes zirconium or oxidically bonded zirconium. Preferably, the surface is then rinsed with fully desalinated water. The substrate obtained is then preferably subjected to a drying step. As can be derived from FIG. 1d, application of the method according to the invention forms on the substrate 1 a metallic or composite protective layer 11 from a first metal into which a second metal or an oxidically bonded second metal, preferably titanium or zirconium, is deposited. This deposit is not just near the surface in the method according to the invention but extends into the volume of the protective layer 11.

The composite protective layer 11 is then subjected to a silanization step, for example by treatment with an alkaline second aqueous system, e.g. at pH 10, containing 3-aminopropyl triethoxysilane, for example in an amount of approx. 10% by weight. The treatment is performed as a no-rinse process. After the treatment with the second aqueous system, the substrate obtained in this way is rinsed with water, preferably desalinated water, e.g. DI water. Silanization is concluded with a drying and a curing step in which a polysiloxane layer 13 is formed.

In order to prevent damage to the metallic protective layer 11 as a result of mechanical influences, a transparent top coat 15 is preferably subsequently applied to this polysiloxane layer 13. This can in particular be a powder clear coat comprising acrylic, polyester or a mixed powder, or wet lacquers can be applied (see also FIG. 1e).

The features of the invention disclosed in the above description, in the drawings and in the claims can be integral both individually and in any combination required in order to realize the invention in its different embodiments.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1.-19. (canceled)

20. A method for producing a corrosion-protected and/or glossy, metallic or non-metallic metal-coated substrate, comprising the following steps:
a) providing at least one substrate with at least one, at least regionally, metal-coatable surface;
c) applying at least one metallic composite protective layer, containing as a main component
at least one first metal selected from the group consisting of aluminum, manganese, magnesium, chrome, and zinc, or
at least one first metal alloy selected from the group consisting of steel, stainless steel, a magnesium alloy, a chrome alloy, and an aluminum alloy, and
at least one second metal and/or at least one oxidically bonded second metal selected from the group consisting of zirconium, titanium, and hafnium distributed as a minor component in the main component, or composed of the main component and the minor component,
wherein method step c) comprises the following sub-steps
i) applying at least one metal layer, containing or composed of the at least one first metal or containing or composed of the at least one first metal alloy, to the coatable surface of the substrate by means of vapor deposition and/or sputtering; and
ii) treating the metal layer according to step i) with at least one first aqueous system, containing at least one first compound of the second metal;
d) silanizing the composite protective layer from step c) ii) by treating said composite protective layer with at least one second aqueous system so as to form at least one polysiloxane layer on the composite protective layer; and
e) applying at least one lacquer layer onto the polysiloxane layer according to step d);
or comprising the following steps:
a′) providing at least one substrate with at least one, at least regionally, metal-coatable surface;
c′) applying at least one metal layer, containing or composed of the at least one first metal selected from the group consisting of aluminum, manganese, magnesium, chrome, and zinc, or containing or composed of the at least one first metal alloy selected from the group consisting of steel, stainless steel, a magnesium alloy, a chrome alloy, and an aluminum alloy, to the coatable surface of the substrate by means of vapor deposition and/or sputtering;
d′) silanizing the metal layer from step c′) by treating said metal layer with at least one second aqueous system so as to form at least one polysiloxane layer on the metal layer; and
e′) applying at least one lacquer layer onto the polysiloxane layer according to step d′).

21. The method according to claim 20, wherein the at least one first aqueous system of step c) ii) is acidic

22. The method according to claim 20, wherein the at least one second aqueous system of step d) and/or step d′) is alkaline.

23. The method according to claim 20, wherein the at least one polysiloxane layer of step d) is formed directly on the composite protective layer.

24. The method according to claim 20, wherein the at least one polysiloxane layer of step d′) is formed directly on the metal layer.

25. The method according to claim 20, wherein the at least one lacquer layer of step e) and/or e′) is applied directly onto the polysiloxane layer.

26. The method according to claim 20, wherein the metallic substrate comprises iron, magnesium, titanium, or aluminum, or metal alloys.

27. The method according to claim 20 wherein the metallic substrate comprises steel, stainless steel, magnesium, titanium or aluminum alloys.

28. The method according to claim 20, wherein the non-metallic substrate comprises glass, ceramics, carbon materials or plastic.

29. The method according to claim 20, wherein the first metal is selected from the group consisting of aluminum, magnesium, and chrome.

30. The method according to claim 20, wherein the first metal alloy is selected from the group consisting of steel, stainless steel, at least one magnesium alloy, at least one chrome alloy, and at least one aluminum alloy.

31. The method according to claim 20, wherein the second metal is selected from the group consisting of zirconium and titanium.

32. The method according to claim 20, wherein the metallic composite protective layer or the metal layer has an average thickness in the range from 5 nm to 500 nm.

33. The method according to claim 20, wherein the metallic composite protective layer or the metal layer has an average thickness in the range from 10 nm to 300 nm.

34. The method according to claim 20, wherein the metallic composite protective layer or the metal layer has an average thickness in the range from 20 nm to 200 nm.

35. The method according to claim 20, wherein the metallic composite protective layer or the metal layer has an average thickness in the range from 50 to 150 nm.

36. The method according to claim 20, wherein the first compound of the second metal comprises at least one oxide, double oxide, oxide hydrate, oxyhalogenide, halogenide, salt and/or an acid.

37. The method according to claim 20, wherein the metal layer is sprayed with the first aqueous system or otherwise treated under pressure, and/or that after applying the metal layer according to step c) i) and prior to the treatment step c) ii) the substrate is subjected to a rinsing step with water.

38. The method according to claim 20, wherein the vapor deposition or sputtering technique in step c) or c′) comprises physical vapor deposition (PVD), vapor deposition using an electron beam vaporizer, vapor deposition using a resistance vaporizer, induction vaporization, ARC vaporization and/or cathode spraying (sputter coating).

39. The method according to claim 20, wherein the second aqueous system comprises at least one silane compound capable of polycondensation and/or polyaddition reactions, in particular hydrolyzable and/or at least partially hydrolyzed silanes.

40. The method according to claim 20, wherein the silane compounds comprise functionalized hydrolyzable and/or partially and/or fully hydrolyzed alkoxysilanes containing amino, acryl, vinyl and/or epoxy groups.

41. The method according to claim 20, wherein the silane compounds are selected from the group consisting of 3-glycidoxypropyl tri(m)ethoxysilane, 3,4-epoxybutyl tri(m)ethoxysilane, 2-(3,4-epoxycyclohexyl)ethyl tri(m)ethoxysilane, 3-(meth)acryloxypropyl tri(m)ethoxysilane, 2-(meth)acryloxyethyl tri(m)ethoxysilane, 3-glycidoxypropyldimethyl(m)ethoxysilane, 3-glycidoxypropylmethyl di(m)ethoxysilane, 3-(meth)acryloxypropylmethyl di(m)ethoxysilane, 2-(meth)acryloxyethylmethyl di(m)ethoxysilane, and any mixtures thereof.

42. The method according to claim 20, wherein silanization according to step d) or d′) is is aborted by treating with water.

43. The method according to claim 20, wherein silane compounds are used for silanization which have functional groups that do not or do not completely react in the silanization step and enter into at least one covalent bond with the materials that form the lacquer layer during the production of said lacquer layer.

44. The method according to claim 20, further comprising between steps a) and c) or a′) and c′) the step:
b) or b′) applying a first base coat layer and optionally a second base coat layer to the metallic substrate, and/or grinding and/or polishing the metallic substrate surface.

45. A metal-coated substrate comprising in this order:
a substrate;
at least one metallic composite protective layer, containing as a main component at least one first metal selected from the group consisting of aluminum, manganese, magnesium, chrome, and zinc, or at least one first metal alloy selected from the group consisting of steel, stainless steel, a magnesium alloy, a chrome alloy, and an aluminum alloy, and at least one second metal and/or at least one oxidically bonded second metal selected from the group consisting of zirconium, titanium, and hafnium distributed as a minor component in this main component, or composed of the at least one main component and the at least one minor component, wherein the first metal or the first metal alloy has been applied as a metal layer by means of vapor deposition or sputtering;
at least one polysiloxane layer present directly on the composite protective layer or at least partially covalently bonded to the composite protective layer;
at least one lacquer layer present directly on the polysiloxane layer or at least partially covalently bonded to the polysiloxane layer; or
a substrate;
at least one metal layer, containing at least one first metal selected from the group consisting of aluminum, manganese, magnesium, chrome, and zinc, or at least one first metal alloy selected from the group consisting of steel, stainless steel, a magnesium alloy, a chrome alloy, and an aluminum alloy, wherein the first metal or the first metal alloy has been applied as a metal layer by means of vapor deposition and/or sputtering;
at least one polysiloxane layer present directly on the metal layer or at least partially covalently bonded to said metal layer; and
at least one lacquer layer present directly on the polysiloxane layer or at least partially covalently bonded to said polysiloxane layer.

46. A metal-coated substrate made according to the method of claim 20.

47. The metal-coated substrate according to claim 45, wherein the second metal and/or the oxidically bonded second metal is distributed in the composite protective layer.

48. The metal-coated substrate according to claim 45, further comprising between the substrate and the metal layer or the composite protective layer a first base coat layer and optionally a second base coat layer.

49. The metal-coated substrate according to claim 45, wherein the metallic substrate comprises aluminum or an aluminum alloy, and the metallic composite protective layer comprises an aluminum layer or a chrome layer as a main component in which titanium, zirconium and/or hafnium, and/or oxidically bonded titanium, zirconium and/or hafnium, is/are distributed as a minor component.

50. A mirror, mirrored material, reflector, headlight, light, lamp, an automobile or motorbike accessory, a wheel rim, a light metal wheel rim, wheel, light metal wheel, a sanitary facility object, a tap, an interior or exterior car body part. a handle, a door handle, a profile or frame, a window frame, a case or packaging, an interior or exterior construction element of a ship, a jewelry object, a furniture piece, an interior or exterior construction element of an airplane, an interior or exterior construction element of a building, a radiator or pipe, a construction element in an elevator, a construction element in an electronic component, a construction element in a communication component, comprising the metal-coated substrate of claim 45.
